(19) United States
(12) Patent Application Publication
(10) Pub. No.: US 2024/0313148 A1
(43) Pub. Date: Sep. 19, 2024

(54) METHOD FOR PRODUCING A RADIATION-EMITTING SEMICONDUCTOR CHIP AND RADIATION-EMITTING SEMICONDUCTOR CHIP

(71) Applicant: ams-OSRAM International GmbH, Regensburg (DE)

(72) Inventors: Laura Kreiner, Regensburg (DE); Jelena Ristic, Regensburg (DE)

(21) Appl. No.: 18/576,646

(22) PCT Filed: Jul. 7, 2022
(86) PCT No.: PCT/EP2022/068939

§ 371 Date: Jan. 4, 2024

(30) Foreign Application Priority Data
Jul. 9, 2021 (DE) 10 2021 207 298.4

(51) Int. Cl. H01L 33/00; H01L 33/42

(52) U.S. Cl. CPC H01L 33/007; H01L 33/0093; H01L 33/42

(57) ABSTRACT

In an embodiment, a method for producing a radiation-emitting semiconductor chip includes providing a substrate, applying an intermediate layer to the substrate, applying a semiconducting layer sequence to the intermediate layer, applying an etch stop layer to the semiconducting layer sequence, epitaxially applying a semiconductor body having an inclined side surface to the etch stop layer and removing the substrate, the intermediate layer and the semiconducting layer sequence up to the etch stop layer.

### CROSS-REFERENCE TO RELATED APPLICATIONS

This patent application is a national phase filing under section 371 of PCT/EP2022/068939, filed Jul. 7, 2022, which claims the priority of German patent application 102021207298.4, filed Jul. 9, 2021, each of which is incorporated herein by reference in its entirety.

### TECHNICAL FIELD

A method for producing a radiation-emitting semiconductor chip is specified. Further, a radiation-emitting semiconductor chip is specified.

### SUMMARY

Embodiments provide a method for producing a radiation-emitting semiconductor chip which is particularly easy to control. Further embodiments provide such a radiation-emitting semiconductor chip.

The radiation-emitting semiconductor chip is, for example, a light-emitting diode, LED for short, in particular a micro-LED. Such a micro-LED comprises, for example, a maximum extension, in particular in lateral directions, of at least 1 μm, in particular of at least 50 μm and at most 1000 μm, in particular of approximately 200 μm.

### SUMMARY

According to at least one embodiment of the method, a substrate is provided. The substrate comprises, for example, a crystalline solid body having a main surface. The main surface comprises, for example, a crystalline surface. Further, the crystalline surface is formed with, for example, a (111) plane of the crystalline solid body. The substrate comprises or consists of, for example, sapphire, gallium nitride, silicon carbide, or silicon.

For example, the substrate comprises a main extension plane. Lateral directions are oriented parallel to the main extension plane, and a vertical direction is oriented perpendicular to the main extension plane. For example, the main surface of the substrate extends in lateral directions.

According to at least one embodiment of the method, an intermediate layer is applied to the substrate. The intermediate layer comprises, for example, a two-dimensional material system or consist thereof. Possible materials for a two-dimensional material include hexagonal boron nitride, graphene, molybdenum sulfite, tungsten selenite, or fluorographene. For example, the interlayer comprises multiple partial layers. In this case, each partial layer is formed from a single monolayer of the two-dimensional material system.

For example, the intermediate layer comprises a thickness in the vertical direction of at least 0.5 nm to at most 100 nm, for example of approximately 3 nm.

The intermediate layer is applied to the substrate by means of chemical vapor deposition (CVD for short), for example. For example, the chemical vapor deposition is a metal organic chemical vapor phase epitaxy (MOVPE for short). Alternatively, the interlayer can be applied by means of an MBE method (molecular beam epitaxy).

According to at least one embodiment of the method, a semiconducting layer sequence is applied to the intermediate layer. The semiconducting layer sequence comprises, for example, a III-V compound semiconductor material. The III-V compound semiconductor material is, for example, a nitride compound semiconductor material. In this case, the compound semiconductor material comprises gallium nitride.

The semiconducting layer sequence is applied to the intermediate layer epitaxially, for example. For example, the semiconducting layer sequence is applied to the intermediate layer by means of a CVD process, in particular a MOVPE process, or an MBE process.

According to at least one embodiment of the method, an etch stop layer is applied to the semiconducting layer sequence. The etch stop layer is formed, for example, with an etch-resistant layer.

Alternatively, the etch stop layer is a predetermined layer with a predetermined material composition. If the predetermined material composition of the etch stop layer is detected during an etching procedure, for example, the etching procedure is stopped.

The etch stop layer comprises or consists of, for example, indium nitride, aluminum nitride and/or gallium nitride. For example, the etch stop layer comprises a thickness in the vertical direction of at least 10 nm and at most 100 nm, for example of approximately 50 nm. Alternatively, the etch stop layer comprises or consists of the material of the intermediate layer or another two-dimensional material system.

According to at least one embodiment of the method, a semiconductor body with an inclined side surface is epitaxially applied to the etch stop layer. For example, the inclined side surface may be grown by an epitaxial process similar to ELOG (epitaxial lateral overgrowth), but without coalescence of adjacent structures. An angle of the inclined side surface to the main extension plane can be predetermined via an interaction of structure dimensions, defined for example by a mask, and growth parameters, such as pressure, temperature, chemical composition, etc.

For example, the semiconductor body is applied epitaxially to the etch stop layer. For example, the semiconductor body is applied to the intermediate layer by means of the CVD process, in particular the MOVPE process.

For example, the semiconductor body is configured to emit electromagnetic radiation. The electromagnetic radiation is, for example, near-ultraviolet radiation, visible radiation, and/or near-infrared radiation. The visible radiation is, for example, light of blue, green, yellow or red color.

For example, the semiconductor body comprises the III-V compound semiconductor material of the semiconducting layer sequence. For example, the semiconductor body comprises a nitride compound semiconductor material, in particular gallium nitride.

For example, the side surface of the semiconductor body encloses an angle of at least 30° and at most 80° with the main extension plane. For example, the angle between the side surface of the semiconductor body and the main extension plane is approximately 50°.

The semiconductor body is grown, for example, on a stack comprising the substrate, the intermediate layer, the semiconducting layer sequence and the etch stop layer. The stack is configured, for example, to produce particularly few distortions during growth of the semiconductor body in the semiconductor body. Thus, a semiconductor body grown in such a way advantageously exhibits particularly few defects.

According to at least one embodiment of the method, the substrate, the intermediate layer and the semiconducting layer sequence are removed up to the etch stop layer. For example, the elements to be removed are removed by means of an etching process. The etching process is, for example, a wet chemical etching process and/or a dry chemical etching process.

Subsequently, the etch stop layer, which is still arranged on the semiconducting layer sequence, for example, is removed. By removing the etch stop layer, the semiconductor body, in particular the first semiconductor layer, is exposed. The etch stop layer is removed, for example, by means of a further dry or wet chemical etching process and/or by means of mechanical grinding and/or by means of polishing. Polishing is, for example, a chemical mechanical polishing process.

After the removal of the interlayer, the exposed first semiconductor layer of the semiconductor body that was covered by the etch stop layer is roughened, for example.

In at least one embodiment, the method for producing a radiation-emitting semiconductor chip comprises providing a substrate, applying an interlayer to the substrate, applying a semiconducting layer sequence to the interlayer, applying an etch stop layer to the semiconducting layer sequence, epitaxially applying a semiconductor body having a inclined side surface to the etch stop layer, and removing the substrate, the interlayer, and the semiconducting layer sequence up to the etch stop layer.

An idea of the method described herein for producing a radiation-emitting semiconductor chip is, among others, that the semiconductor body is produced on an intermediate layer, which is in particular a two-dimensional material system. Two-dimensional material systems, when stacked on top of each other in the vertical direction, comprise, for example, a bonding force in the vertical direction that is many times smaller than a bonding force in lateral directions. Thus, the substrate is advantageously particularly easy to detach from the semiconductor body. Furthermore, such a detached substrate is advantageously reusable. Such a process is thus advantageously particularly cost-efficient.

Furthermore, an etch stop layer is arranged between the semiconductor body and the semiconducting layer sequence. By ablating the elements up to the etch stop layer, the semiconductor body is advantageously produced in a particularly simple manner.

According to at least one embodiment of the method, the semiconductor body comprises a first semiconductor layer of a first doping type, a second semiconductor layer of a second doping type different from the first doping type, and an active region.

For example, the active region comprises a pn junction, a double heterostructure, a single quantum well structure, or a multiple quantum well structure to generate the electromagnetic radiation.

For example, the first semiconductor layer faces the substrate. For example, the first semiconductor layer comprises first dopants of an n-type. Thus, the first doping type is, for example, an n-doped type.

The second semiconductor layer faces away from the substrate, for example. The second semiconductor layer comprises second dopants of a p-type, for example. Thus, the first doping type is a p-doped type, for example.

According to at least one embodiment of the method, the active region is arranged between the first semiconductor layer and the second semiconductor layer. The active region is configured, for example, to generate electromagnetic radiation.

According to at least one embodiment of the method, an angle between the inclined side surface of the semiconductor body and the vertical direction is predeterminable as a function of at least one growth parameter. The growth parameter is for example a growth pressure, a growth temperature and/or a dopant concentration.

The dopants are, for example, magnesium and/or silicon. The first semiconductor layer comprises, for example, silicon as a dopant and the second semiconductor layer comprises, for example, magnesium as a dopant. A dopant concentration of the dopants is respectively, for example, at least 5·1017 cm-3 and at most 5·1018 cm-3.

Such an epitaxially produced inclined side surface of the semiconductor body does not, for example, have to be subsequently structured further. In particular, the incline is advantageously not produced by an etching process. Such an etching process induces, for example, defects in the region of the inclined side surface, which act as non-radiative recombination centers. The etching process thus increases, for example, non-radiative recombinations at the inclined side surface.

In the present method, however, the inclined side surface of the semiconductor body is produced epitaxially, so that the semiconductor body comprises a lower defect density in the region of the inclined side surface than in the region of an inclined side surface produced by means of an etching process. A radiation-emitting semiconductor chip produced in this way is advantageously particularly effective and emits electromagnetic radiation particularly homogeneously over its entire radiation exit surface.

According to at least one embodiment of the method, a mask with at least one opening is applied to the substrate. In the opening, the substrate is freely accessible, for example.

For example, the mask comprises or consists of silicon nitride or silicon dioxide. For example, the intermediate layer is applied to the freely accessible substrate and the mask. Alternatively, the intermediate layer can be applied directly to the substrate over the entire surface, and then the mask can be applied to the intermediate layer and subsequently patterned.

For example, a material of the mask is applied to the substrate over its entire surface. The material of the mask is applied to the substrate, for example, by means of plasma-enhanced chemical vapor deposition (PECVD for short). The opening is created by means of a photolithographic process, for example.

For example, multiple openings are created in the material of the mask. Advantageously, this allows several radiation-emitting semiconductor chips to be produced.

For example, the mask comprises a thickness in the vertical direction of at least 100 nm and at most 1000 nm, in particular of approximately 400 nm.

A shape of the semiconductor body in lateral directions is predetermined, for example, by a shape of the opening in lateral directions. The opening is, for example, round, oval, triangular, quadrangular or hexagonal in plan view. Thus, advantageously, a shape of the semiconductor body is also formed, for example, round, oval, triangular, quadrangular or hexagonal in plan view. Different semiconductor bodies can, for example, be structured in different sizes, in particular also in the combination of different sizes and shapes on one substrate.

According to at least one embodiment of the method, the semiconducting layer sequence comprises a seed layer and another semiconductor layer of the first doping type.

The seed layer comprises, for example, AlGaN. The aluminum comprises, for example, a molar fraction in the seed layer of at least 10% and at most 20%, in particular approximately 14%. Furthermore, the seed layer comprises, for example, a thickness in the vertical direction of at least 50 nm and at most 500 nm, in particular approximately 200 nm.

The further semiconductor layer comprises, for example, (Al;In;Ga)N. The further semiconductor layer is formed from the same material as the first semiconductor layer, for example. That is, the further semiconductor layer comprises, for example, the first dopant.

According to at least one embodiment of the method, the seed layer is applied to the intermediate layer arranged in the opening on the substrate.

The intermediate layer, which is arranged on the substrate, comprises a crystalline crystal structure, for example. The seed layer is grown on such a crystalline crystal structure, for example. The intermediate layer arranged on the mask comprises, for example, an amorphous crystal structure on which the seed layer is not and/or not crystalline grown. For example, the material of the seed layer that is applied to the mask, in particular to a top surface and to a side surface of the mask, does not comprise a crystalline form. That is, a residual material layer formed with amorphous remnants of the material of the seed layer is arranged on the mask, in particular between the mask and the seed layer.

According to at least one embodiment of the method, the further semiconductor layer is applied to the seed layer. The seed layer is configured, for example, to act as a buffer layer between the epitaxially grown further semiconductor layer and the intermediate layer. Thus, such a seed layer advantageously promotes nucleation of the further semiconductor layer.

A further semiconductor layer applied in this way also preferably comprises a particularly low defect density. Thus, the semiconductor body is also advantageously formed in a particularly defect-free manner.

According to at least one embodiment of the method, the further semiconductor layer overgrows the mask in lateral directions. That is, the further semiconductor layer protrudes the opening in lateral directions. Furthermore, on the further semiconductor layer, the grown first semiconductor layer overgrows the mask in lateral directions. That is, the first semiconductor layer protrudes the opening in lateral directions.

According to at least one embodiment, the further semiconductor layer expands in a direction facing away from the substrate. This direction is parallel to the vertical direction, for example.

According to at least one embodiment of the method, the semiconductor body tapers in a direction facing away from the substrate.

According to at least one embodiment of the method, the intermediate layer comprises hexagonal boron nitride, graphene, molybdenum sulfite, tungsten selenite, or fluorographene. For example, the intermediate layer arranged in the opening on the substrate is formed with a plurality of partial layers of hexagonal boron nitride, graphene, molybdenum sulfite, tungsten selenite, or fluorographene. For example, a thickness of a partial layer of hexagonal boron nitride along the vertical direction is about 0.33 nm.

The intermediate layer, which is arranged on the mask, for example, comprises irregularly arranged boron and nitride atoms.

According to at least one embodiment of the method, the semiconductor chip is configured to generate electromagnetic radiation during operation.

According to at least one embodiment of the method, a peak wavelength of the electromagnetic radiation is predeterminable as a function of an indium and/or aluminum content of the semiconductor body. In particular, the peak wavelength of the electromagnetic radiation is predeterminable as a function of the indium and/or aluminum content of the active region.

Advantageously, different radiation-emitting semiconductor chips can be produced with this method, in particular with the specified method steps, wherein the indium and/or aluminum content is predeterminable particularly easily during the growth of the active region. Thus, radiation-emitting semiconductor chips having different peak wavelengths from each other can be produced advantageously with the method described herein without substantially changing the method.

According to at least one embodiment of the method, a first electrode layer is applied to a first main surface of the semiconductor body facing away from the substrate. The first electrode layer comprises, for example, a metal or consists thereof. The first electrode layer is configured, for example, to be contacted from the outside.

According to at least one embodiment of the method, the semiconductor body is arranged on a temporary carrier before removing the substrate, the intermediate layer, the seed layer and the further semiconductor layer. The temporary carrier forms a mechanically stabilizing component of the radiation-emitting semiconductor chip for subsequent method steps.

According to at least one embodiment of the method, the substrate is removed along the interlayer. For example, the interlayer comprises bonding forces in the vertical direction that are many times lower than bonding forces in lateral directions. Advantageously, the substrate can thus be separated particularly easily. Advantageously, such a substrate can be reusable.

According to at least one embodiment of the method, the seed layer is removed after removing the substrate. Furthermore, during removing the seed layer, for example, the residual material layer is also removed. The removing is performed, for example, with a wet chemical etching process and/or a dry chemical etching process.

According to at least one embodiment of the method, after removing the seed layer, the first semiconductor layer is removed up to the etch stop layer.

According to at least one embodiment, a second electrode layer is applied to a second main surface of the semiconductor body opposite the first main surface. The second electrode layer comprises, for example, electrically conductive metals or transparent electrically conductive oxides (TCO) or is formed therefrom. For example, zinc oxide, tin oxide, cadmium oxide, titanium oxide, indium oxide or indium tin oxide (ITO) are TCOs. For example, the TCOs are provided with a dopant. The dopant is configured, for example, to give the TCOs electrically conductive properties.

According to at least one embodiment of the method, a mirror layer is applied to the inclined side surface. For example, the mirror layer completely covers the inclined side surface. In particular, the mirror layer completely covers all side surfaces of the semiconductor body.

The mirror layer comprises, for example, several partial layers. The partial layers each comprise, for example, a dielectric material and/or a metal. Preferably, the mirror layer comprises alternately arranged partial layers of a high refractive index material and a low refractive index material, and a metal as the outermost layer. For example, the mirror layer is a dielectric mirror such as a Bragg mirror in combination with a metal mirror.

For example, the mirror layer comprises a reflectivity of at least 90%, preferably at least 99%, for the generated electromagnetic radiation.

A radiation-emitting semiconductor chip is further specified. In particular, the radiation-emitting semiconductor chip can be produced by the method for producing a radiation-emitting semiconductor chip described herein. That is, a radiation-emitting semiconductor chip described herein is producible by the described method or is produced by the described method. Therefore, all features disclosed in connection with the method are also disclosed in connection with the radiation-emitting semiconductor chip, and vice versa.

According to at least one embodiment, the radiation-emitting semiconductor chip comprises a semiconductor body configured to emit electromagnetic radiation.

According to at least one embodiment of the radiation-emitting semiconductor chip, the semiconductor body comprises an inclined side surface.

According to at least one embodiment of the radiation-emitting semiconductor chip, the inclined side surface is produced epitaxially.

Such a semiconductor body with such an epitaxially produced inclined side surface advantageously comprises fewer non-radiative recombination centers in the region of the inclined side surface than a semiconductor body in which the inclined side surface is produced by an etching process.

Advantageously, such an epitaxially generated inclined side surface suppresses unwanted recombination.

In particular, it is possible that the inclined side surface extends over the entire side of the semiconductor body. Further, it is possible that the semiconductor body is laterally bounded exclusively by inclined side surfaces which connect a top surface with a bottom surface of the semiconductor body.

According to at least one embodiment of the radiation-emitting semiconductor chip, the semiconductor body comprises a first main surface and an opposite second main surface.

According to at least one embodiment of the radiation-emitting semiconductor chip, a first electrode layer is arranged on the first main surface.

According to at least one embodiment of the radiation-emitting semiconductor chip, a second electrode layer is arranged on the second main surface.

According to at least one embodiment of the radiation-emitting semiconductor chip, the second electrode layer is transparent for the generated electromagnetic radiation. For example, the second electrode layer is configured to absorb at most 4%, in particular at most 2%, of the generated electromagnetic radiation. That is, the second electrode layer transmits at least 96%, in particular at least 98%, of the generated electromagnetic radiation.

Further disclosed is a radiation-emitting semiconductor device. The radiation-emitting semiconductor device includes a radiation-emitting semiconductor chip described herein. Therefore, all features disclosed in connection with the radiation-emitting semiconductor chip are also disclosed in connection with the radiation-emitting semiconductor device, and vice versa.

According to at least one embodiment, the radiation-emitting semiconductor device comprises a cladding body that surrounds the inclined side surface of the semiconductor body in lateral directions. For example, the cladding body completely covers the inclined side surface. For example, the cladding body comprises or consists of silicon dioxide.

According to at least one embodiment of the radiation-emitting semiconductor device, a connection element which is in electrically conductive contact with the second electrode layer is arranged on the cladding body. For example, the connection element comprises a metal or consists thereof. The connection element is configured, for example, to be contactable from the outside.

According to at least one embodiment of the radiation-emitting semiconductor device, a connection element that is in electrically conductive contact with the second electrode layer extends completely through the cladding body. For example, the cladding body comprises a recess that completely penetrates the cladding body in the vertical direction. In this case, the connection element is arranged in the recess.

Alternatively, the connection element is arranged on a side surface of the cladding body and extends in the vertical direction over the entire cladding body, in particular over the entire side surface.

Furthermore, a radiation-emitting semiconductor device comprising at least two radiation-emitting semiconductor chips described herein is specified. All features disclosed in connection with the radiation-emitting semiconductor chip are therefore also disclosed in connection with the radiation-emitting semiconductor device, and vice versa.

According to at least one embodiment, the radiation-emitting semiconductor device comprises a carrier on which the radiation-emitting semiconductor chips are arranged. The carrier is, for example, a mechanically stabilizing component of the radiation-emitting semiconductor chips. The carrier can be, for example, a printed circuit board (PCB for short) or a leadframe.

According to at least one embodiment of the radiation-emitting semiconductor device, at least some of the radiation-emitting semiconductor chips are configured to emit electromagnetic radiation having peak wavelengths different from one another. In particular, all of the radiation-emitting semiconductor chips are produced by a method described herein.

According to at least one embodiment of the radiation-emitting semiconductor device, each radiation-emitting semiconductor chip comprises a separate second electrode layer. For example, on each of the radiation-emitting semiconductor chips, a separate second electrode layer is arranged.

According to at least one embodiment of the radiation-emitting semiconductor device, all radiation-emitting semiconductor chips comprise a common second electrode layer.

In the following, the method for producing the radiation-emitting semiconductor chip, the radiation-emitting semiconductor chip, and the radiation-emitting semiconductor device are explained in more detail with reference to the figures according to exemplary embodiments.

### BRIEF DESCRIPTION OF THE DRAWINGS

FIGS. 1, 2, 3, 4, 5, and 6 show schematic sectional views of method stages in the production of a radiation-emitting semiconductor chip according to an exemplary embodiment;

FIGS. 7 and 8 show schematic sectional views of method stages in the production of a radiation-emitting semiconductor chip according to one exemplary embodiment each;

FIG. 9 shows a schematic sectional view of a radiation-emitting semiconductor chip according to an exemplary embodiment;

FIG. 10 shows a schematic sectional view of a radiation-emitting semiconductor device according to an exemplary embodiment; and

FIGS. 11 and 12 each show a schematic sectional view of a radiation-emitting semiconductor device according to an exemplary embodiment.

### DETAILED DESCRIPTION OF ILLUSTRATIVE EMBODIMENTS

Elements that are identical, similar or have the same effect are provided with the same reference signs in the figures.

In the method stage according to FIG. 1, a substrate 2 is provided to which an intermediate layer 3, a semiconducting layer sequence 4, an etch stop layer 7 and a semiconductor body 8 are applied by means of a mask 13.

After providing the substrate 2, a mask 13 is applied to the substrate 2. The mask 13 comprises an opening 14 in which the substrate 2 is freely accessible. The mask 13 comprises, for example, a thickness in the vertical direction of approximately 400 nm.

Subsequently, an intermediate layer 3 is applied. A material of the intermediate layer 3 is applied to the substrate 2, which is freely accessible in the opening 14, and to the mask 13. Here, the substrate 2 is heated to a temperature of approximately 1300° C. during applying the material of the intermediate layer 3. The material of the intermediate layer 3 comprises, for example, boron and nitride. Thus, partial layers of hexagonal boron nitride are produced on the substrate 2.

For example, the produced intermediate layer 3 comprises a thickness in the vertical direction of 3 nm. Such a thickness corresponds in particular to ten partial layers of hexagonal boron nitride. In particular, the partial layers comprise a bonding force in the vertical direction that is many times smaller than a bonding force of the atoms within the partial layers in lateral directions.

The material of the intermediate layer 3 applied to the mask 13 does not change into a crystalline state. In particular, it is an amorphous boron nitride layer.

Subsequently, the semiconducting layer sequence 4 is applied to the intermediate layer 3 in the opening 14. The semiconducting layer sequence 4 comprises a seed layer 5 and a further semiconductor layer.

The seed layer 5 is applied directly to the intermediate layer 3 in the opening 14. Here, the substrate 2 and the intermediate layer 3 are heated to a temperature of approximately 1100° C. during applying the material of the seed layer 5. The material of the seed layer 5 comprises, for example, AlGaN and comprises a thickness in the vertical direction of approximately 200 nm.

Since the intermediate layer 3, in particular the material of the intermediate layer 3, is in an amorphous state on the mask 13, the material of the seed layer 5 also grows amorphously in these regions rather than crystalline. Accordingly, the mask 13 is completely surrounded by a residual material layer 15 comprising the material of the seed layer 5. The residual material layer 15 is thus arranged between the mask 13 and the seed layer 5.

The further semiconductor layer 6 is subsequently grown on the seed layer 5. The further semiconductor layer 6 comprises, for example, GaN, which comprises first dopants. The first dopants are Si, in particular. The further semiconductor layer 6 further comprises a thickness in the vertical direction of approximately 150 nm.

The further semiconductor layer 6 overgrows the mask 13 in lateral directions. A side surface of the further semiconductor layer 6 is formed inclined. The side surface is formed inclined in such a way that the further semiconductor layer 6 expands in a direction facing away from the substrate 2. Thus, the further semiconductor layer 6 protrudes the opening 14 in lateral directions.

An etch stop layer 7 is subsequently applied to the further semiconductor layer 6. The etch stop layer 7 completely covers a main surface of the further semiconductor layer 6 facing away from the substrate 2. The etch stop layer 7 comprises InN, AlN or GaN and comprises a thickness in the vertical direction of approximately 50 nm.

Subsequently, the semiconductor body 8 is applied to the etch stop layer 7, in particular the first semiconductor layer 10 is subsequently applied to the etch stop layer 7. The first semiconductor layer 10 comprises, for example, GaN comprising first dopants. The first dopants are Si, in particular. The first semiconductor layer 10 further comprises a thickness in the vertical direction of approximately 150 nm.

An active region 11 is applied to the first semiconductor layer 10. The active region 11 comprises, for example, a multiple quantum well structure. Barrier layers of the multiple quantum well structure comprise, for example, GaN and quantum well layers comprise, for example, InGaN. Here, the In content of the active region 11 is predeterminable.

A peak wavelength of an electromagnetic radiation to be generated in the active region 11 is predeterminable in particular as a function of the indium content of the active region 11.

The second semiconductor layer 12 is subsequently applied to the active region 11. The second semiconductor layer 12 comprises, for example, GaN comprising second dopants. The second dopants are in particular Mg. The second semiconductor layer 12 further comprises a thickness in the vertical direction of approximately 175 nm.

Furthermore, the semiconductor body 8 comprises an inclined side surface 9. The inclined side surface 9 is formed in such a way that the semiconductor body 8 tapers in a direction facing away from the substrate 2.

An angle between the inclined side surface 9 of the semiconductor body 8 and the vertical direction is predeterminable as a function of at least one growth parameter. For example, the angle between the inclined side surface 9 and the vertical direction is approximately 60°.

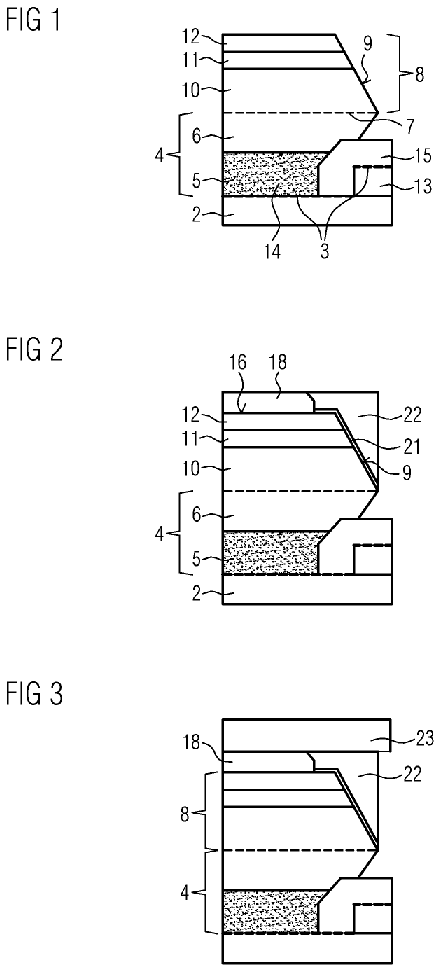

In the method stage according to FIG. 2, a first electrode layer 18 is applied to the semiconductor body 8. In particular, the first electrode layer 18 is applied to a first main surface 16 of the semiconductor body 8 facing away from the substrate 2. In particular, the first electrode layer 18 is applied to the second semiconductor layer 12.

Furthermore, a mirror layer 21 is applied to the inclined side surface 9. The mirror layer 21 is further arranged on the first main surface 16 of the semiconductor body 8, which is not covered by the first electrode layer 18. The mirror layer 21 is, for example, a Bragg mirror.

Thus, the generated electromagnetic radiation can be coupled out particularly effectively via the radiation exit surface 24, as shown in FIG. 9.

Subsequently, a cladding body 22 is applied to the semiconductor body 8. The cladding body 22 completely surrounds the semiconductor body 8. Furthermore, the cladding body 22 completely covers the mirror layer 21. The cladding body 22 terminates flush with the first electrode layer 18 in the vertical direction.

A temporary carrier 23 is subsequently arranged on the first electrode layer 18 according to FIG. 3. The temporary carrier 23 forms a mechanically stabilizing component for the arrangement for subsequent method steps.

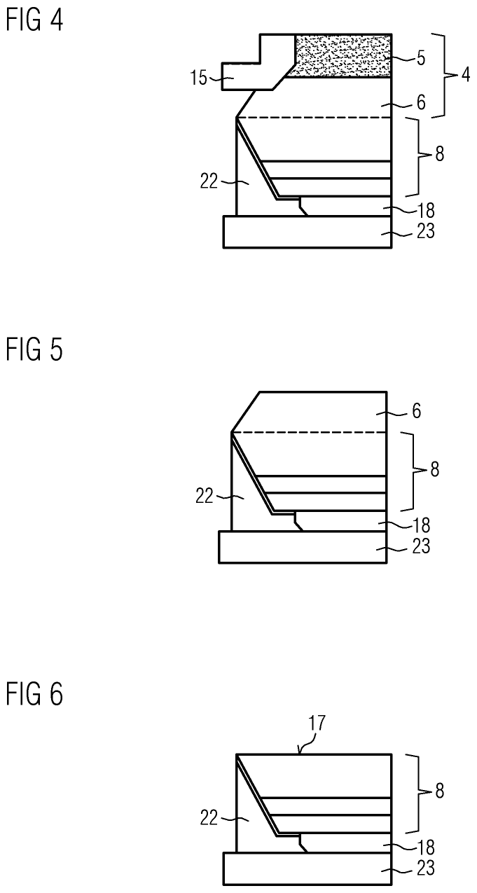

In the method stage shown in FIG. 4, the substrate 2 with the mask 13 is removed. Since the interlayer 3 does not comprise high bonding forces in the vertical direction, the substrate 2 and the mask 13 can be removed non-destructively. Thus, the substrate 2 with the mask 13 can be reused.

According to FIG. 5, the seed layer 5 and the residual layer 15 are removed.

Subsequently, in the method stage according to FIG. 6, the further semiconductor layer 6 is removed up to the etch stop layer 7. For example, the further semiconductor layer 6 is removed up to the etch stop layer 7 by means of an etching process. The etching process is, for example, a wet chemical etching process and/or a dry chemical etching process.

The etch stop layer 7 remaining on the semiconductor body 8 is subsequently removed, for example by means of a grinding process, so that a second main surface 17 of the semiconductor body 8, in particular the first semiconductor layer 10, is exposed. In particular, it is possible that the inclined side surface 9 extends over the entire side of the semiconductor body 8. Further, it is possible that the semiconductor body 8 is laterally bounded exclusively by inclined side surfaces which connect a top surface to a bottom surface of the semiconductor body 8.

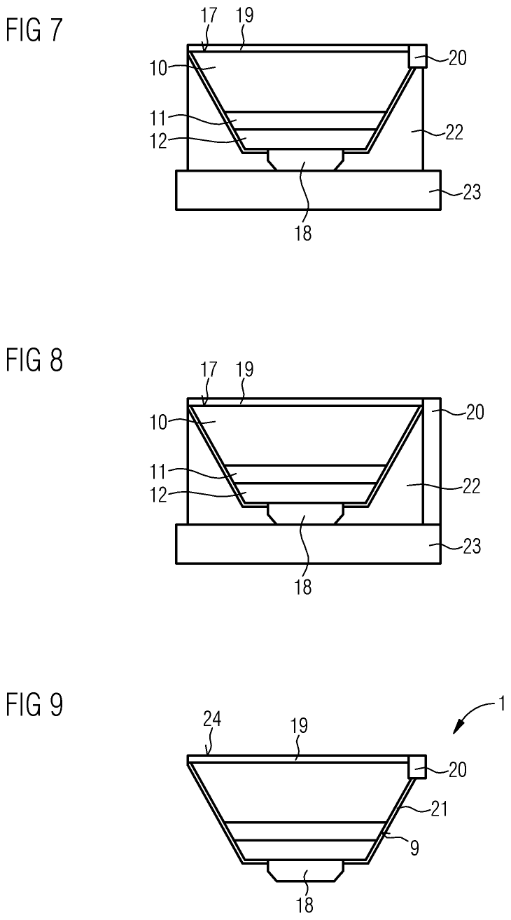

According to FIGS. 7 and 8, a second electrode layer 19 is arranged on the exposed first semiconductor layer 10 on the second main surface 17 of the semiconductor body 8. The second electrode layer 19 completely covers the second main surface 17 and is formed with a material transparent for electromagnetic radiation.

Furthermore, a connection element 20 is produced which is electrically conductive, in particular in direct contact, with the second electrode layer 19.

In FIG. 7, the connection element 20 is arranged on the cladding body 22 and extends only partially in the vertical direction into the cladding body 22. A radiation-emitting semiconductor chip 1 produced in this way can be contacted from two opposite sides.

According to FIG. 8, the connection element 20 is arranged on a side surface of the cladding body 22. The connection element 20 extends completely over the side surface of the cladding body 22 in the vertical direction. A radiation-emitting semiconductor chip 1 produced in this way is contactable from a common side by means of the first electrode layer 18 and the connection element 20.

Subsequently, the temporary carrier 23 is removed.

The radiation-emitting semiconductor chip 1 according to the exemplary embodiment of FIG. 9 comprises a semiconductor body 8 configured to emit electromagnetic radiation. The semiconductor body 8 comprises an inclined side surface 9, wherein the inclined side surface 9 is produced epitaxially. In particular, the semiconductor body is produced by the method specified herein.

By means of an inclined side surface 9 produced in this way, non-radiative recombination is advantageously suppressed, so that such a radiation-emitting semiconductor chip 1 is formed particularly effectively. The electromagnetic radiation is coupled out via a radiation exit surface 24 which is arranged opposite the first electrode layer 18.

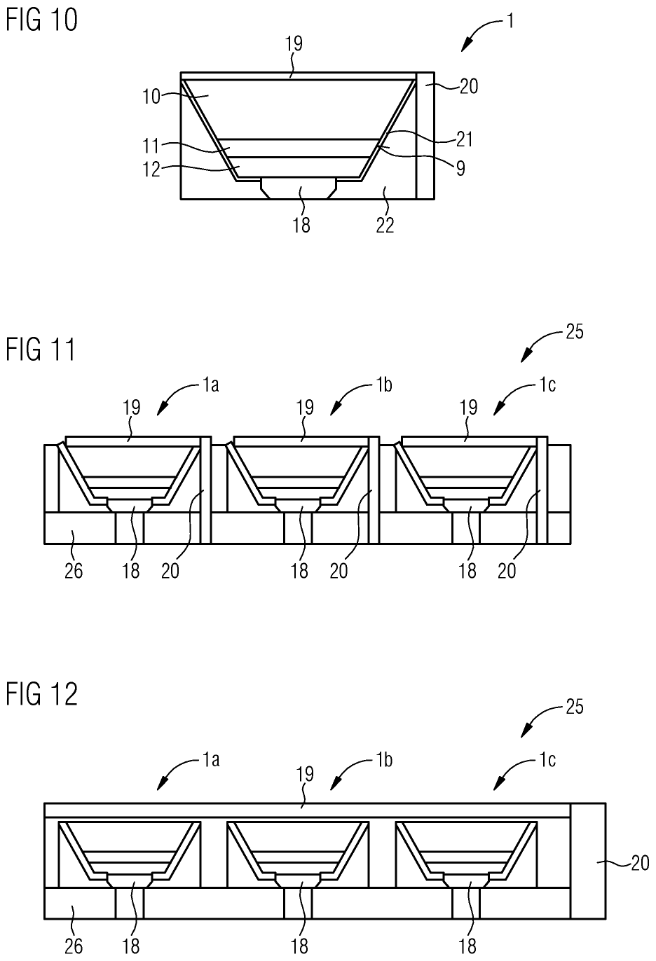

The radiation-emitting semiconductor device 25 according to the exemplary embodiment of FIG. 10 comprises a radiation-emitting semiconductor chip 1 according to FIG. 9 and is arranged in a cladding body 22. In particular, the cladding body 22 is not applied to the semiconductor body 8 during the method. According to this exemplary embodiment, the radiation-emitting semiconductor chip 1 is placed in a cladding body 22 which comprises a cavity and is produced separately.

The radiation-emitting semiconductor device 25 according to the exemplary embodiments of FIGS. 11 and 12 each comprises a plurality of radiation-emitting semiconductor chips 1, here for example three different ones. The radiation-emitting semiconductor chips 1 are arranged on a carrier 26 through which the radiation-emitting semiconductor chips 1 are contacted.

The radiation-emitting semiconductor chips 1 are configured to emit electromagnetic radiation having peak wavelengths different from one another. The radiation-emitting semiconductor chip 1a arranged in the left region on the carrier 26 emits blue light, for example, the radiation-emitting semiconductor chip 1b arranged in the central region on the carrier 26 emits green light, for example, and the radiation-emitting semiconductor chip 1c arranged in the right region on the carrier 26 emits red light, for example. Thus, the methods described herein can be used to produce radiation-emitting semiconductor chips 1 that are used in particular in an RGB display.

According to FIG. 11, a single second electrode layer 19 is arranged on each semiconductor body 8. Each second electrode layer 19 is electrically conductively connected to a single connection element 20.

In contrast to the exemplary embodiment of FIG. 11, in the exemplary embodiment of FIG. 12, a common second electrode layer 19 is arranged on the semiconductor body 8. The common second electrode layer 19 covers each of the semiconductor bodies 8. The common second electrode layer 19 is electrically conductively connected to a single common connection element 20.

The features and exemplary embodiments described in connection with the figures can be combined with each other according to further exemplary embodiments, even if not all combinations are explicitly described. Furthermore, the exemplary embodiments described in connection with the figures may alternatively or additionally comprise further features according to the description in the general part.

By the description based on the exemplary embodiments, the invention is not restricted to these. Rather, the invention encompasses any new feature as well as any combination of features, which in particular includes any combination of features in the patent claims, even if this feature or combination itself is not explicitly stated in the patent claims or exemplary embodiments.

This patent application claims the priority of the German patent application 102021207298.4, the disclosure content of which is here incorporated by reference.

1.-20. (canceled)

21. A method for producing a radiation-emitting semiconductor chip, the method comprising:
providing a substrate;
applying an intermediate layer to the substrate;
applying a semiconducting layer sequence to the intermediate layer;
applying an etch stop layer to the semiconducting layer sequence;
epitaxially applying a semiconductor body having an inclined side surface to the etch stop layer; and
removing the substrate, the intermediate layer and the semiconducting layer sequence up to the etch stop layer.

22. The method according to claim 21,
wherein the semiconductor body comprises a first semiconductor layer of a first doping type, a second semiconductor layer of a second doping type different from the first doping type, and an active region, and
wherein the active region is arranged between the first semiconductor layer and the second semiconductor layer.

23. The method according to claim 21, wherein an angle between the inclined side surface of the semiconductor body and a vertical direction is predeterminable as a function of at least one growth parameter.

24. The method according to claim 21, further comprising:
applying a mask with at least one opening to the substrate,
wherein the semiconducting layer sequence comprises a seed layer and a further semiconductor layer of a first doping type,
wherein the seed layer is applied to the intermediate layer arranged in the opening on the substrate, and
wherein the further semiconductor layer is applied to the seed layer.

25. The method according to claim 24,
wherein the further semiconductor layer overgrows the mask in lateral directions during application, and
wherein the further semiconductor layer expands in a direction facing away from the substrate.

26. The method according to claim 21, wherein the semiconductor body tapers in a direction facing away from the substrate.

27. The method according to claim 21, wherein the intermediate layer comprises hexagonal boron nitride, graphene, molybdenum sulfite, tungsten selenite, or fluorographene.

28. The method according to claim 21,
wherein the radiation-emitting semiconductor chip is configured to generate electromagnetic radiation, and
wherein a peak wavelength of the electromagnetic radiation is predeterminable as a function of an indium and/or aluminum content of the semiconductor body.

29. The method according to claim 21, wherein a first electrode layer is applied to a first main surface of the semiconductor body facing away from the substrate.

30. The method according to claim 21,
wherein the semiconductor body is arranged on a temporary carrier before removing the substrate, the intermediate layer, a seed layer and the further semiconductor layer, and
wherein the substrate is removed along the intermediate layer.

31. The method according to claim 30,
wherein, after removing the substrate, the seed layer is removed, and
wherein, after removing the seed layer, a semiconductor layer is removed up to the etch stop layer.

32. The method according to claim 29, wherein a second electrode layer is applied to a second main surface of the semiconductor body opposite to the first main surface.

33. The method according to claim 29, wherein a mirror layer is applied to the inclined side surface.

34. A radiation-emitting semiconductor device comprising:
a radiation-emitting semiconductor chip comprising:
a semiconductor body configured to emit electromagnetic radiation,
wherein the semiconductor body comprises an inclined side surface,
wherein the inclined side surface is an epitaxially produced inclined surface, and
wherein the semiconductor body comprises a first main surface and an opposite second main surface and
a second electrode layer arranged on the second main surface;
a cladding body surrounding the inclined side surface of the semiconductor body in lateral directions; and
a connection element in electrically conductive contact with the second electrode layer arranged on the cladding body,
wherein the radiation-emitting semiconductor chip is a micro-LED.

35. The radiation-emitting semiconductor device according to claim 34, further comprising a first electrode layer is arranged on the first main surface.

36. The radiation-emitting semiconductor device according to claim 34, wherein the second electrode layer is transparent for generated electromagnetic radiation.

37. The radiation-emitting semiconductor device according to claim 34, wherein the connection element extends completely through the cladding body.

38. A radiation-emitting semiconductor device comprising:
at least two radiation-emitting semiconductor chips having a semiconductor body configured to emit electromagnetic radiation,
wherein the semiconductor body comprises an inclined side surface,
wherein the inclined side surface is an epitaxially produced inclined surface, and
wherein the radiation-emitting semiconductor chip is a micro-LED; and
a carrier on which the radiation-emitting semiconductor chips are arranged,
wherein at least some of the radiation-emitting semiconductor chips are configured to emit electromagnetic radiation with peak wavelengths different from one another,
wherein each radiation-emitting semiconductor chip comprises a separate second electrode layer, or
wherein all radiation-emitting semiconductor chips comprise a common second electrode layer.
